(19) United States
(12) Patent Application Publication
(10) Pub. No.: US 2012/0017977 A1
(43) Pub. Date: Jan. 26, 2012

(54) PHOTOELECTRIC CONVERSION SEMICONDUCTOR LAYER, MANUFACTURING METHOD THEREOF, PHOTOELECTRIC CONVERSION DEVICE, AND SOLAR CELL

(75) Inventors: Tadanobu Satou, Ashigarakami-gun (JP); Makoto Kikuchi, Ashigarakami-gun (JP)

(73) Assignee: FUJIFILM CORPORATION, Minato-Ku, Tokyo (JP)

(21) Appl. No.: 13/260,425

(22) PCT Filed: Mar. 23, 2010
(86) PCT No.: PCT/JP2010/055489

§ 371 Date: Sep. 26, 2011

(30) Foreign Application Priority Data
Mar. 26, 2009 (JP) 2009-076517
Oct. 6, 2009 (JP) 2009-232122

(51) Int. Cl. H01L 31/0352; H01L 31/18

(52) U.S. Cl. 136/255; 438/63; 257/E31.032

(57) ABSTRACT

A photoelectric conversion semiconductor layer is provided which is capable of providing a potential gradient in the thickness direction, can be manufactured at a lower cost than a layer formed by vacuum film forming, and capable of providing high photoelectric conversion efficiency. The photoelectric conversion semiconductor layer is a layer that generates a current by absorbing light and is formed of a particle layer in which a plurality of particles is disposed in plane and thickness directions. Preferably, the photoelectric conversion semiconductor layer includes, as the plurality of particles, a plurality of types of particles having different band-gaps, and the potential in the thickness direction of the layer is distributed.

### TECHNICAL FIELD

The present invention relates to a photoelectric conversion semiconductor layer and a manufacturing method thereof, a photoelectric conversion device using the same, and a solar cell.

### BACKGROUND ART

Photoelectric conversion devices, having a laminated structure in which a lower electrode (rear electrode), a photoelectric conversion semiconductor layer that generates a current by absorbing light, and an upper electrode are stacked, are used in various applications, such as solar cells and the like. Most of the conventional solar cells are Si-based cells using bulk monocrystalline Si, polycrystalline Si, or thin film amorphous Si. Recently, however, research and development of compound semiconductor-based solar cells that do not depend on Si has been carried out. Two types of compound semiconductor-based solar cells are known, one of which is a bulk system, such as GaAs system and the like, and the other of which is a thin film system, such as CIS (Cu—In—Se) system formed of a group Ib element, a group IIIb element, and a group VIb element, CIGS (Cu—In—Ga—Se), or the like. The CIS system or CIGS system has a high light absorption rate and high energy conversion efficiency is reported.

As for methods of manufacturing CIGS layers, three-stage approach, selenidation method, and the like are known. These methods, however, employ vacuum film forming, requiring a high manufacturing cost and a large equipment investment. Consequently, methods in which spherical particles containing constituent elements of CIGS are coated and sintered are proposed as non-vacuum methods capable of manufacturing CIGS layers at low cost as described, for example, in U.S. Patent Application Publication No. 20050183768 (Patent Document 1), U.S. Patent Application Publication No. 20060062902 (Patent Document 2), International Patent Publication No. WO2008/013383 (Patent Document 3), “Nanoparticle derived Cu(In,Ga) Se₂ absorber layer for thin film solar cells”, S. Ahn et al., Colloids and Surface A: Physicochemical and Engineering Aspects, Vols. 313-314, pp. 171-174, 2008 (Non-Patent Document 1), “Effects of heat treatments on the properties of Cu(In,Ga)Seₑ nanoparticles”, S. Ahn et al., Solar Energy Materials and Solar Cells, Vol. 91, Issue 19, pp. 1836-1841, 2007 (Non-Patent Document 2), and “CIS and CIGS layers from selenized nanoparticle precursors”, M. Kaelin et al., Thin Solid Films, Vols. 431-432, pp. 58-62, 2003 (Non-Patent Document 3).

Non-Patent Documents 1 and 2 propose methods in which spherical particles are coated on a substrate and sintered at a high temperature around 500° C. to crystallize the particles. These documents discuss reduction of heating time by a rapid thermal process (RTP).

Patent Document 1, and Non-Patent Documents 2 and 3 propose methods in which one or more types of spherical oxide or alloy particles containing Cu, In, and Ga are coated on a substrate and heat treated at a high temperature around 500° C. in the presence of Se gas to selenide and crystallize the particles.

Patent Documents 2 and 3 propose methods in which core-shell particles, made of a core and shell having different compositions, are used as a raw material, which are coated on a substrate and sintered at a high temperature around 500° C. to crystallize the particles. The method described in Patent Document 2 uses a particle with the core including group Ib, IIIa, and VIa elements and the shell including group Ib, IIa and/or VIa elements. The method described in Patent Document 3 uses a particle with the core including In and Se, and the shell including Cu and Se.

In the mean time, it is known that the photoelectric conversion efficiency of a CIGS photoelectric conversion layer or the like can be improved by varying the density of Ga or the like in a thickness direction thereof to vary a potential (band-gap) in the thickness direction. As for potential gradient structures, a single grating structure and a double grating structure are known and the double grating structure is thought to be more preferable.

The aforementioned methods that include a particle sintering process, crystal growth of particles occurs due to melting and/or fusion of the particles and the overall composition is unified, so that a composition gradient can not be provided in the thickness direction. For example, Patent Documents 2 and 3 describe that a CIGS layer with a uniform composition is formed by sintering even though core-shell particles are used. In order to vary the composition of a photoelectric conversion layer in the thickness direction, it is necessary to form the layer at a temperature that does not cause melting and/or fusion of the particles.

“Monograin layer solar cells”, M. Altosaar et al., Thin Solid Films, Vols. 431-432, pp. 466-469, 2003 (Non-Patent Document 4), “Further developments in CIS monograin layer solar cells technology”, M. Altosaar et al., Solar Energy Materials and Solar Cells, Vol. 87, Issues 1-4, pp. 25-32, 2005 (Non-Patent Document 5), and “In-situ X-ray diffraction study of the initial dealloying of Cu₃Au(001) and Cu_{0.83}Pd_{0.17}(001)” F. U. Renner et al., Thin Solid Films, Vol. 515, Issue 14, pp. 5574-5580, 2007 (Non-Patent Document 6) propose methods in which spherical CIGS particles are coated on a substrate and thereafter high temperature heat treatment is not implemented. In the methods described in Non-Patent Documents 4 to 6, shapes and compositions of the particles remain as they are after the layer is formed because the methods do not include a sintering process. Non-Patent Documents 4 to 6 describe only a single particle layer in which a plurality of spherical particles is disposed only in a plane direction.

“Synthesis of Colloidal CuGaSe₂, CuInSe₂, and Cu(InGa)Se₂ Nanoparticles”, J. Tang et al., Chem. Mater., Vol. 20, pp. 6906-6910, 2008 (Non-Patent Document 7) describes a method for synthesizing plate-like CIGS particles. Non-Patent Document 7 reports only the particle synthesis and describes neither the utilization of the particles as a material of a photoelectric conversion layer nor a specific method for forming a photoelectric conversion layer.

In the methods described in Patent Documents 1 to 3 and Non-Patent Documents 1 to 3, even if particles having different compositions are stacked, the overall composition is unified due to sintering, so that a composition gradient can not be provided. Further, in the methods described in Patent Documents 1 to 3 and Non-Patent Documents 1 to 3, when trying to obtain a photoelectric conversion layer having a required thickness by a single coating, the photoelectric conversion layer, in most cases, becomes island-shaped. Even when a uniform layer appears to be formed, instead of an island-shaped layer, many voids are formed in the layer due to burning of an organic component, such as a dispersant, resulting in increased crystal defects and reduced light absorption, whereby a high efficient photoelectric conversion layer can not be provided. Consequently, in the methods described in these documents, the coating of the particles and sintering are repeated a plurality of times to reduce the voids in the crystal layer and to provide a highly homogeneous crystal layer. Such method, however, increases the number of process steps, making it difficult to realize a low manufacturing cost through a non-vacuum process.

In the CIGS layer of a single particle layer in which a plurality of spherical particles is disposed only in a plane direction, a composition gradient can not be provided in the thickness direction of the layer.

Heretofore, no report has been found that describes a particle photoelectric conversion layer in which a composition gradient is provided in the thickness direction to provide a potential gradient in the thickness direction, and photoelectric conversion efficiency comparable to that of a photoelectric conversion layer formed by vacuum film forming has not been achieved. For example, in Non-Patent Document 7 reports a conversion efficiency of 9.5% when non-light receiving areas such as the electrode are excluded. This corresponds to 5.7% in the standard measure of conversion efficiency. The value of 5.7% is less than half of that of the photoelectric conversion efficiency of the CIGS layer formed through vacuum film forming, proving that it is an unpractical level. The methods described in Non-Patent Documents 4 to 6 also include a step of flattening a portion of spherical particles by etching in order to improve the conversion efficiency by increasing the contact area between the particles and electrodes.

The present invention has been developed in view of the circumstances described above, and it is an object of the present invention to provide a photoelectric conversion semiconductor layer capable of providing a potential gradient in the thickness direction, can be manufactured at a lower cost than a layer formed by vacuum film forming, and capable of providing a higher photoelectric conversion efficiency than a layer formed by conventional non-vacuum film forming. It is a further object of the present invention to provide a method of manufacturing the photoelectric conversion semiconductor layer described above.

### DISCLOSURE OF THE INVENTION

A photoelectric conversion semiconductor layer of the present invention is a layer that generates a current by absorbing light and is constituted by a particle layer in which a plurality of particles is disposed in a plane direction and a thickness direction.

A first photoelectric conversion semiconductor layer manufacturing method of the present invention is a method of manufacturing the photoelectric conversion semiconductor layer of the present invention described above and includes the step of coating the plurality of particles or a coating material that includes the plurality of particles and a dispersion medium on a substrate.

A second photoelectric conversion semiconductor layer manufacturing method of the present invention is a method of manufacturing the photoelectric conversion semiconductor layer of the present invention described above and includes the steps of coating the plurality of particles or a coating material that includes the plurality of particles and a dispersion medium on a substrate and removing the dispersion medium. Preferably, the step of removing the dispersion medium is a step performed at a temperature not higher than 250° C.

A photoelectric conversion device of the present invention is a device that includes the photoelectric conversion semiconductor layer of the present invention and electrodes for extracting a current generated in the photoelectric conversion semiconductor layer.

According to a preferable aspect of the invention, a photoelectric conversion device that uses a flexible substrate is provided, in which the photoelectric conversion semiconductor layer and the electrodes are provided on the flexible substrate.

As for the flexible substrate described above, one of the following is preferably used: an anodized substrate constituted by an Al base consisting primarily of Al and having an Al₂O₃ based anodized film on at least either one of the sides; an anodized substrate constituted by a composite base having an Al₂O₃ based anodized film on at least either one of the sides, the composite base being made of a Fe material primarily consisting of Fe with an Al material primarily consisting of Al combined to at least either one of the sides of the Fe material; or an anodized substrate constituted by a composite base having an Al₂O₃ based anodized film on at least either one of the sides, the composite base being made of a Fe material primarily consisting of Fe with an Al film primarily consisting of Al formed on at least either one of the sides of the Fe material. The term “Fe material primarily consisting of Fe” as used herein refers to that the Fe content of material is 60% by mass or more.

A solar cell of the present invention is a solar cell that includes the photoelectric conversion device of the present invention described above.

According to the present invention, a photoelectric conversion semiconductor layer capable of providing a potential gradient in the thickness direction, can be manufactured at a lower cost than a layer formed by vacuum film forming, and capable of providing a higher photoelectric conversion efficiency than a layer formed by conventional non-vacuum film forming, and a method of manufacturing the layer may be provided.

### BRIEF DESCRIPTION OF THE DRAWINGS

FIG. 1A is a sectional view of a photoelectric conversion semiconductor layer according to a preferred embodiment of the present invention.

FIG. 1B is a sectional view of a photoelectric conversion semiconductor layer according to another preferred embodiment of the present invention.

FIG. 2 illustrates a single grating structure and a double grating structure.

FIG. 3 illustrates the relationship between the lattice constant and band gap of I-III-VI compound semiconductors.

FIG. 4A is a schematic sectional view of a photoelectric conversion device according to an embodiment of the present invention taken along a lateral direction.

FIG. 4B is a schematic sectional view of a photoelectric conversion device according to an embodiment of the present invention taken along a longitudinal direction.

FIG. 5 schematically illustrates the structures of two anodized substrates.

FIG. 6 is a perspective view of an anodized substrate illustrating a manufacturing method thereof.

FIG. 7 is a TEM surface photograph of a plate-like particle.

### BEST MODE FOR CARRYING OUT THE INVENTION

### [Photoelectric Conversion Semiconductor Layer]

A photoelectric conversion semiconductor layer of the present invention is a layer that generates a current by absorbing light and is formed of a particle layer in which a plurality of particles is disposed in a plane direction and a thickness direction.

There is not any specific restriction on the shape of the plurality of particles and spherical and/or plate-like particles are preferably used. There is not any specific restriction on the surface shape of the plate-like particles, and one of a substantially hexagonal shape, a triangular shape, a circular shape, and a rectangular shape is preferably used. The inventor of the present invention has succeeded in synthesizing a plate-like particle having a substantially hexagonal shape, a triangular shape, a circular shape, or a rectangular shape when “Examples” were produced which will be described later.

The term “plate-like particle” as used herein refers to a particle having a pair of opposite main surfaces. Here, the “main surface” refers to a surface having a largest area of all of the outer surfaces of the particle. The term “surface shape of the plate-like particle” as used herein refers to the shape of the main surface. The term “a substantially hexagonal shape (a substantially triangular shape, or a substantially rectangular shape)” as used herein refers to a hexagonal shape (a triangular shape, or a rectangular shape) and the hexagonal shape (triangular shape, or rectangular shape) with a rounded corner. The term “a substantially circular shape” as used herein refers to a circular shape and a round shape similar to the circular shape.

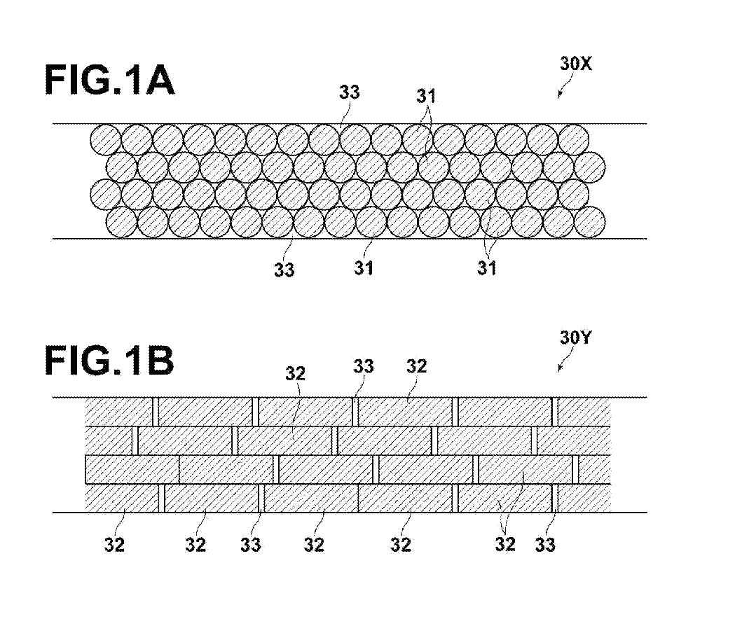

Photoelectric conversion semiconductor layers according to preferred embodiments of the present invention will be described with reference to the accompanying drawings. FIGS. 1A and 1B are schematic cross-sectional views of photoelectric conversion semiconductor layers according to preferred embodiments of the present invention. Note that each component is not drawn to scale in the drawings.

Photoelectric conversion semiconductor layer 30X shown in FIG. 1A is a layer formed of a particle layer having a laminated structure in which a plurality of spherical particles 31 is disposed in the plane and thickness directions. Photoelectric conversion semiconductor layer 30Y shown in FIG. 1B is a layer formed of a particle layer having a laminated structure in which a plurality of plate-like particles 32 is disposed in the plane and thickness directions. FIGS. 1A and 1B show 4-layer structures as examples. In photoelectric conversion semiconductor layer 30X or 30Y, gap 33 may or may not be present between adjacent particles.

The photoelectric conversion semiconductor layer of the present invention is produced by a method having a step of coating the plurality of spherical or plate-like particles described above or a coating material that includes the particles. The photoelectric conversion semiconductor layer of the present invention is produced without heat treatment at a temperature higher than 250° C., and therefore the particles used for producing the layer remain as they are without sintered.

The photoelectric conversion semiconductor layer of the present invention may be formed of one type of particles having the same composition or a plurality of types of particles having different compositions. The photoelectric conversion semiconductor layer of the present invention is manufactured without subjected to sintering at a temperature higher than 250° C. Thus, when a plurality of types of particles having different compositions is used, the compositions are not unified and each composition is maintained as it is even after the layer is formed.

Preferably, the photoelectric conversion semiconductor layer of the present invention includes, as the plurality of particles, a plurality of types of particles having different band-gaps and the potential of the layer in the thickness direction is distributed. Such structure allows a higher design value for the photoelectric conversion efficiency.

There is not any specific restriction on the potential (band-gap) gradient structure in the thickness direction, and may have a single grating structure in which a graph representing the relationship between the position of the layer in the thickness direction and the potential has one slope, a double grating structure in which a graph representing the relationship between the position of the layer in the thickness direction and the potential has two different slopes, a grating structure in which a graph representing the relationship between the position of the layer in the thickness direction and the potential has three or more slopes, or the like.

Preferably, the photoelectric conversion semiconductor layer of the present invention has a potential gradient structure in which a graph representing the relationship between the position of the layer in the thickness direction and the potential has a plurality of different slopes, and particularly preferable to have a double grating structure in which a graph representing the relationship between the position of the layer in the thickness direction and the potential has two different slopes.

In any grating structure, it is said that carriers induced by light are more likely to reach the electrode due to acceleration by an electric field generated inside thereof by the gradient of the band structure, whereby the probability of recombination in the recombination center is reduced and the photoelectric conversion efficiency is enhanced (International Patent Publication No. WO2004/090995 and the like). For details of the single grating structure and double grating structure, refer to “A new approach to high-efficiency solar cells by band gap grading in Cu(In,Ga)Seₑ chalcopyrite semiconductors”, T. Dullweber et al., Solar Energy Materials and Solar Cells, Vol. 67, pp. 145-150, 2001 and the like.

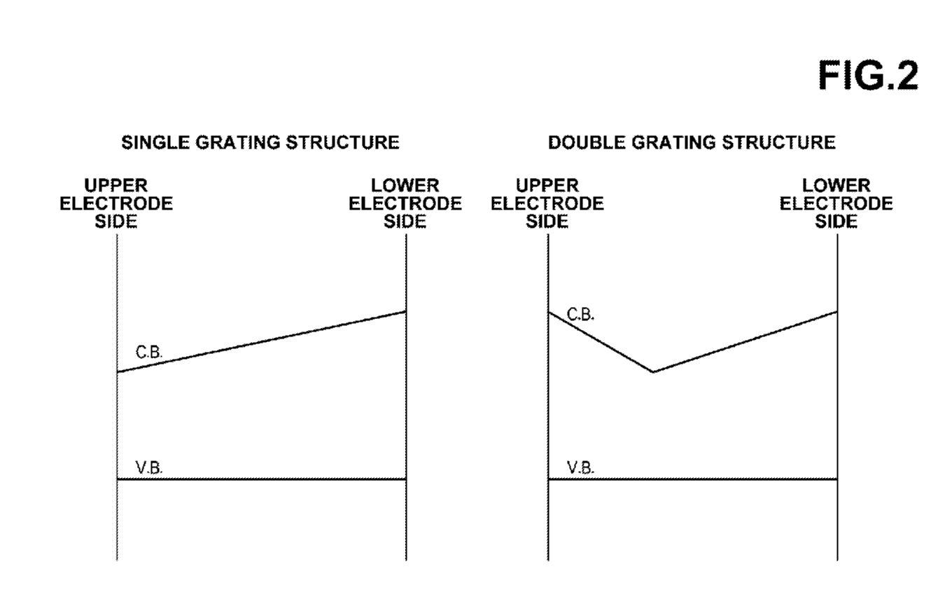

FIG. 2 schematically illustrates example conduction band (C.B.) and valence band (V.B.) in a thickness direction in each of the single and double grating structures. In the single grating structure, C.B. gradually decreases from the lower electrode side toward the upper electrode side. In the double grating structure, C.B. gradually decreases from the lower electrode side toward the upper electrode side but gradually increases from a certain position. Whereas the graph representing the relationship between the position in the thickness direction and potential has one slope in the single grating structure, the graph representing the relationship between the position in the thickness direction and potential has two slopes in the double grating structure and the two slopes have different (positive and negative) signs.

There is not any specific restriction on the size and number of layers of the particles to form the photoelectric conversion semiconductor layer of the present invention. A smaller average particle thickness (average diameter of spherical particles, average thickness of plate-like particles) and a greater number of particle layers allow easy potential variation in the thickness direction. An excessively small average particle thickness and an excessively large number of particle layers, however, result in an increased number of grain boundaries between the electrodes and the photoelectric conversion efficiency is reduced.

Preferably, the average particle thickness (average diameter of spherical particles, average thickness of plate-like particles) is in the range from 0.05 to 1.0 μm when easy provision of potential gradient in the thickness direction, photoelectric conversion efficiency, and easy manufacture of the particles are taken into account.

In the photoelectric conversion semiconductor layer of the present invention, there is not any specific restriction on the volume filling rate representing the ratio of the total volume of the plurality of particles to the volume of the entire layer. In order to increase the light absorption and prevent defects which cause loss in carrier movement, a higher particle filling rate is desirable for the photoelectric conversion semiconductor layer. More specifically, it is preferable that the photoelectric conversion semiconductor layer has a particle filling rate of 50% or more. Hereinafter, unless otherwise specifically indicated, the “filling rate” refers to “volume filling rate representing the ratio of the total volume of the plurality of particles to the volume of the entire layer”.

For spherical particles having an aspect ratio (aspect ratio of the cross-section of the photoelectric conversion layer in the thickness direction) of 3.0 or less, it is preferable that the particles have a true or substantially true spherical shape rather than an uneven surface shape. Also from the standpoint of small surface friction, it is preferable that the particles have a true or substantially true spherical shape.

For spherical particles having an aspect ratio of 3.0 or less, a moderate particle diameter distribution tends to increase the filling rate since a relatively small diameter particle enters between relatively large diameter particles and the packing becomes denser. But, if the particle diameter distribution becomes excessively wide and the amount of small particles having a size smaller than the critical particle size, at which the repulsion between the particles becomes relatively high, is increased, the filling rate tends to decrease.

Preferably, the coefficient of variation (dispersion degree) of particle diameter is in the range from 20 to 60% for spherical particles having an aspect ratio of 3.0 or less. Use of particles having such dispersion degree allows a particle filling rate of 50% or more to be obtained constantly, whereby high efficient photoelectric conversion layers with a high light absorption rate and less defects which cause loss in carrier movement may be formed stably.

There is not any specific restriction on the aspect ratio of plate-like particles (cross-sectional aspect ratio in thickness direction of photoelectric conversion layer) constituting the photoelectric conversion semiconductor layer of the present invention. For a nearly cubic less anisotropic shape, it is difficult to dispose a plurality of plate-like particles such that the main surfaces of the particles are arranged parallel to the surface of the substrate. A higher aspect ratio shape is preferable because it allows easy disposition of a plurality of particles with the main surfaces being arranged parallel to the surface of the substrate. Preferably, the aspect ratio of the plurality of plate-like particles is 3 to 50 when the orientation of the particles, i.e., ease of manufacture of the photoelectric conversion semiconductor layer is taken into account.

There is not any specific restriction on the coefficient of variation (dispersion degree) of the average equivalent circle diameter of plate-like particles constituting the photoelectric conversion semiconductor layer of the present invention. A larger diameter is more preferable because a larger value provides a larger light receiving area. Preferably, the average equivalent circle diameter of a plurality of plate-like particles is, for example, in the range from 0.1 to 100 μm when the photoelectric conversion efficiency and ease of manufacture of the photoelectric conversion semiconductor layer are taken into account.

There is not any specific restriction on the coefficient of variation (dispersion degree) of equivalent circle diameter of a plurality of plate-like particles, and it is preferable that the coefficient of variation is monodisperse or close to it in order to manufacture the photoelectric conversion semiconductor layer with a stable quality. More specifically, it is preferable that the coefficient of variation of equivalent circle diameter is less than 40% and more preferably less than 30%.

As described in Chemical Engineering Handbook, six types of filling patterns are defined for spherical particles and each of the filling patterns can be identified by a TEM observation. Where the particles have the same diameter, i.e., the particles have no particle diameter distribution, the void ratio is constant for different particle diameters. The total void ratio may be obtained by obtaining the particle diameter distribution, obtaining the ratio of a certain particle diameter and void ratio thereof, and integrating the void ratio with respect to the overall particle diameter distribution. Then the filling rate may be calculated as follows. That is, filling rate (volume filling rate)=100−void ratio (%).

Here, the “average equivalent circle diameter of particle” is evaluated with a transmission electron microscope (TEM) regardless of the shape of the particle. For example, Scanning Transmission Electron Microscope HD-2700 (Hitachi) or the like may be used for the evaluation. The “average equivalent circle diameter” is calculated by obtaining diameters of circles circumscribing approximately 300 particles and averaging the diameters. The “coefficient of variation of equivalent circle diameter (dispersion degree)” is statistically obtained from the particle diameter evaluation using the TEM.

The “thickness of particle” is calculated in the following manner regardless of the shape of the particle. That is, multiple particles are distributed on a mesh and carbon or the like is deposited at a given angle from above to implement shadowing, which is then photographed by a scanning electron microscope (SEM) or the like. Thereafter, the thickness of each particle is calculated based on the length of the shadow obtained from the image and the deposition angle. The average value of the thickness is obtained by averaging the thicknesses of about 300 particles as in the equivalent circle diameter. The “aspect ratio of each particle” is calculated from the equivalent circle diameter and thickness obtained in the manner as described above.

Preferably, the major component of the photoelectric conversion semiconductor layer is at least one type of compound semiconductor having a chalcopyrite structure. Preferably, the major component of the photoelectric conversion semiconductor layer is at least one type of compound semiconductor formed of a group Ib element, a group IIIb element, and a group VIb element.

As having a high light absorption rate and providing high photoelectric conversion efficiency, it is preferable that the major component of the photoelectric conversion layer is at least one type of compound semiconductor (5) formed of at least one type of group Ib element selected from the group consisting of Cu and Ag, at least one type of group IIIb element selected from the group consisting of Al, Ga, and In, and at least one type of group VIb element selected from the group consisting of S, Se, and Te.

Element group representation herein is based on the short period periodic table. A compound semiconductor formed of a group Ib element, a group IIIb element, and a group VI element is sometimes represented herein as “group I-III-VI semiconductor” for short. Each of the group Ib element, group IIIb element, and group VIb element, which are constituent elements of group I-III-VI semiconductor, may be one type or two or more types of elements.

Compound semiconductors (S) include CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ)(S, Se)₂, Ag(In₁₋ₓGaₓ)Se₂, Ag(In₁₋ₓGaₓ)(S, Se)₂, and the like.

It is particularly preferable that the photoelectric conversion semiconductor layer includes CuInS₂, CuInSe₂ (CIS), or these compounds solidified with Ga, i.e, Cu(In,Ga)S₂, Cu(In,Ga)Se₂, or compounds of these selenium sulfides. The photoelectric conversion semiconductor layer may include one or more types of these. CIS, CIGS, and the like are reported to have a high light absorption rate and high energy conversion efficiency. Further, they are excellent in the durability with less deterioration in the conversion efficiency due to light exposure and the like.

If the photoelectric conversion semiconductor layer is a CIGS layer, there is not any specific restriction on the Ga concentration and Cu concentration in the layer. Preferably, a molar ratio of Ga content with respect to the total content of group III elements in the layer is in the range from 0.05 to 0.6, more preferably in the range from 0.2 to 0.5. Preferably, a molar ratio of Cu content with respect to the total content of group III elements in the layer is in the range from 0.70 to 1.0, more preferably in the range from 0.8 to 0.98.

The photoelectric conversion semiconductor layer of the present invention includes an impurity for obtaining an intended semiconductor conductivity type. The impurity may be included in the photoelectric conversion semiconductor layer by diffusing from an adjacent layer and/or active doping.

The photoelectric conversion semiconductor layer of the present invention may include one or more types of semiconductors other than the group semiconductor. Semiconductors other than the group semiconductor may include but not limited to a semiconductor of group IVb element, such as Si (group IV semiconductor), a semiconductor of group IIIb element and group Vb element such as GaAs (group III-V semiconductor), and a semiconductor of group IIb element and group VIb element, such as CdTe (group II-VI semiconductor).

The photoelectric conversion semiconductor layer of the present invention may include any arbitrary component other than semiconductors and an impurity for causing the semiconductors to become an intended conductivity type within a limit that does not affect the properties.

The photoelectric conversion semiconductor layer may have a concentration distribution of an impurity, and may have a plurality of layer regions of different semiconductivities, such as n-type, p-type, i-type, and the like.

The photoelectric conversion semiconductor layer may be formed of one type of particles having the same composition or a plurality of types of particles having different compositions. But it has already been described that the photoelectric conversion semiconductor layer of the present invention is preferable to include, as the plurality of particles, a plurality of types of particles having different band-gaps and the potential of the layer in the thickness direction is distributed.

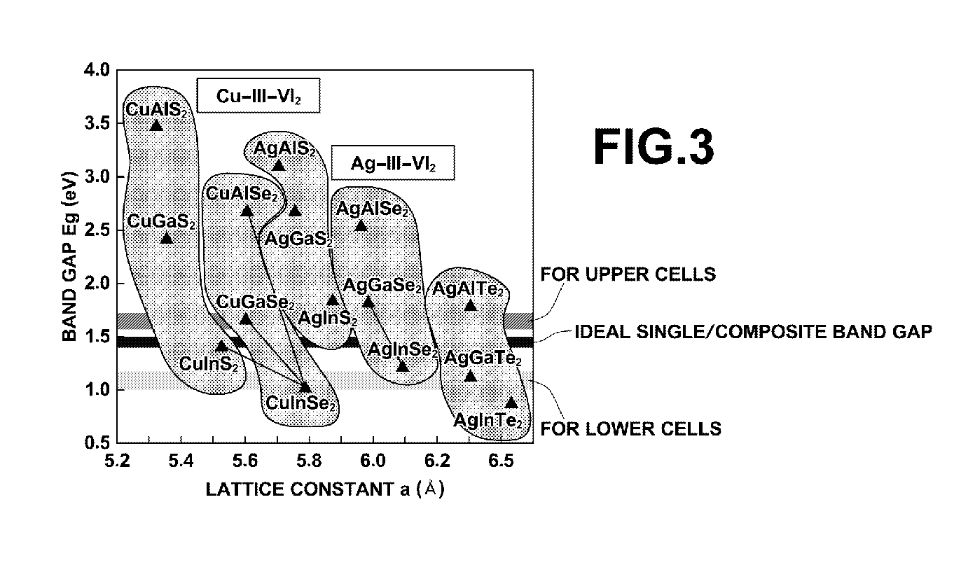

FIG. 3 illustrates the relationship between the lattice constant and band-gap of major compound semiconductors. FIG. 3 shows that various band-gaps may be obtained by changing the composition ratio. That is, the potential of the layer in the thickness direction can be varied by the use of, as the plurality of particles, a plurality of types of particles having different concentrations of at least one of group Ib, IIIb, and VIb elements and changing the concentration of the element in the thickness direction.

For the compound semiconductors (S) described above, the element for changing the concentration in the thickness direction is at least one type of element selected from the group consisting of Cu, Ag, Al, Ga, In, S, Se, and Te, and more preferably at least one type of element selected from the group consisting of Ag, Ga, Al, and S.

For example, composition gradation structures in which Ga concentration in Cu(In,Ga)Se₂ (CIGS) in the thickness direction is changed, Al concentration in Cu(In,Al)Se₂ in the thickness direction is changed, Ag concentration in (Cu,Ag)(In,Ga)Se₂ in the thickness direction is changed, and S concentration in Cu(In,Ga)(S,Se)₂ in the thickness direction is changed may be cited. In the case of CIGS, for example, the potential may be changed in the range from 1.04 to 1.68 eV by changing the Ga concentration. When providing a gradient in the Ga concentration in CIGS, there is not any specific restriction on the minimum Ga concentration which, when the maximum Ga concentration of the particles is assumed to be 1, is preferable in the range from 0.2 to 0.9, more preferably in the range from 0.3 to 0.8, and particularly preferable in the range from 0.4 to 0.6.

The distribution of the composition may be evaluated by measuring equipment of FE-TEM, which is capable of narrowing the electron beam, with an EDAX attached thereto. The distribution of the composition may also be measured from the half bandwidth of emission spectrum using the method disclosed in International Patent Publication No. WO2006/009124. Generally, different compositions of the particles result in different band-gaps, and thus the emission wavelengths due to recombination of the excited electrons are also different. Consequently, a broad composition distribution of the particles results in a broad emission spectrum.

The correlation between the half bandwidth of emission spectrum and composition distribution of particles may be confirmed by measuring the composition of the particles with the EDAX attached to the FE-TEM and taking the correlation with the emission spectrum. There is not any specific restriction on the wavelength of the excitation light used for measuring the emission spectrum, which is preferably in the range from near ultraviolet region to visible light region, more preferably in the range from 150 to 800 nm, and particularly preferably in the range from 400 to 700 nm.

For example, in the actual measurement results carried out by the inventor of the present invention, in which the average Ga element ratio with respect to the total element ratio of In and Ga was set to 0.5 in a CIGS and excited with 550 nm, the half bandwidth of emission spectrum was 450 nm when the coefficient of variation was 60% and 200 nm when the coefficient of variation was 300. In this way, the half bandwidth of the emission spectrum reflects the distribution of the composition of the particles.

There is not any specific restriction on the half bandwidth of emission spectrum and, for example in the case of a CIGS, is preferable to be in the range from 5 to 450 nm. The lower limit of nm is due to thermal fluctuation and any half bandwidth lower than that is theoretically impossible.

(Photoelectric Conversion Semiconductor Layer Manufacturing Method)

A first photoelectric conversion semiconductor layer manufacturing method of the present invention is a method that includes the step of coating, on a substrate, a plurality of particles or a coating material that includes a plurality of particles and a dispersion medium.

A second photoelectric conversion semiconductor layer manufacturing method of the present invention is a method that includes the step of coating, on a substrate, a coating material that includes a plurality of particles and a dispersion medium and the step of removing the dispersion medium. Preferably, the step of removing the dispersion medium is performed at a temperature not higher than 250° C.

### <Particle Manufacturing Method>

There is not any specific restriction on the method for manufacturing particles used in the photoelectric conversion semiconductor layer of the present invention. Spherical particle manufacturing methods are described in Patent Documents 1 to 3 and Non-Patent Documents 1 to 6 recited under the “Background Art”. In the past, a manufacturing method of plate-like particles has been reported only in Non-Patent Document 7. The inventor of the present invention has succeeded in synthesizing plate-like particles by a novel method which is different from the known method described in Non-Patent Document 7 (refer to “Examples” described later).

Metal-chalcogen particles may be manufactured by gas phase methods, liquid phase methods, or other particle forming methods of compound semiconductors. When the avoidance of particle aggregation and mass productivity are taken into account, liquid phase methods are preferable. Liquid phase methods include, for example, polymer existence method, high boiling point solvent method, regular micelle method, and reverse micelle method.

A preferable method for manufacturing metal-chalcogen particles is to cause reaction between the metal and chalcogen, which are in the form of salt or complex, in an alcohol based solvent and/or in an aqueous solution. In this method, the reaction is implemented through a metathetical reaction or a reduction reaction.

Particles having desired shapes and sizes may be manufactured by adjusting reaction conditions. For example, the inventor of the present invention has found that the shape and size of obtainable particles can be changed by changing pH of the reaction solution (refer to “Examples” described later).

Metal salts or metal complexes include metallic halides, metallic sulfides, metallic nitrates, metallic sulfates, metallic phosphates, metallic complex salts, ammonium complex salts, chloro complex salts, hydroxo complex salts, cyano complex salts, metal alcoholates, metal phenolates, metallic carbonates, metallic carboxylate salts, metallic hydrides, metallic organic compounds, and the like. Chalcogen salts or chalcogen complexes include alkali metal salts and alkali, alkaline earth metal salt, and the like. In addition, thioacetamides, thiols, and the like may be used as the source of the chalcogen.

Alcohol based solvents include methanol, ethanol, propanol, butanol, methoxyethanol, ethoxyethanol, ethoxypropanol, tetrafluoropropanol, and the like, in which ethoxyethanol, ethoxypropanol, or tetrafluoropropanol is preferably used.

There is not any specific restriction on the reducing agent used for reducing the metal compounds and, for example, hydrogen, sodium tetrahydroborate, hydrazine, hydroxylamine, ascorbic acid, dextrin, superhydride (LiB(C₂H₅)₃H), alcohols, and the like may be cited.

When causing the reaction described above, it is preferable to use an adsorption group containing low molecular dispersant. As for the adsorption group containing low molecular dispersant, those soluble in alcohol based solvents or water are used. Preferably, the molecular mass of the low molecular dispersant is not greater than 300, more preferably not greater than 200. As for the adsorption group, —SH, —CN, —SO₂OH, —COOH, and the like are preferably used, but not limited to these. It is also preferable to have a plurality of these groups. As for the dispersant, compounds represented by R—SH, R—NH₂, R—COOH, HS—R′—(SO₃H)ₙ, HS—R′—NH₂, HS—R′—(COOH)ₙ, and the like are preferable.

In the chemical formulae above, R represents an aliphatic group, an aromatic group, or a heterocyclic group (group in which one hydrogen atom is removed from a heterocyclic ring), R′ represents a group in which a hydrogen atom of R is further substituted. As for R′, alkylene groups, arylene groups, and heterocyclic ring linking groups (group in which two hydrogen atoms are removed from a heterocyclic ring) are preferable. As for the aromatic group, substituted or non-substituted phenyl groups and naphthyl groups are preferable. As for the heterocyclic ring of the heterocyclic group or heterocyclic ring linking group, azoles, diazoles, thiadiazole, triazoles, tetrazoles, and the like are preferable. A preferable value of “n” is from 1 to 3. Examples of adsorption group containing low molecular dispersants include mercaptopropanesulfonate, mercaptosuccinic acid, octanethiol, dodecanethiol, thiophenol, thiocresol, mercaptobenzimidazole, mercaptobenzothiazole, 5-amino-2-mercapto thiadiazole, 2-mercapto-3-phenylimidazole, 1-dithiazolyl butyl carboxylic acid, and the like. Preferably, the additive amount of the dispersant is 0.5 to 5 times by mol of the particles produced and more preferably 1 to 3 times by mol.

Preferably, the reaction temperature is in the range from 0 to 200° C. and more preferably in the range from 0 to 100° C. The relative proportion in the intended composition ratio is used for the molar ratio of the salt or complex salt to be added. The adsorption group containing low molecular dispersant may be added to the solution before, during, or after reaction.

The reaction may be implemented in an agitated reaction vessel, and a magnetic driven sealed type small space agitator may be used. As for the magnetic driven sealed type small space agitator, device (A) disclosed in Japanese Unexamined Patent Publication No. 10 (1998)-043570 may be cited as an example. It is preferable to use an agitator having a greater shearing force is used after using the magnetic driven sealed type small space agitator. The agitator having a greater shearing force is an agitator having basically turbine or paddle type agitation blades with a sharp cutting edge located at the tip of each blade or at a position where each blade meets. Specific examples include Dissolver (Nihon-tokusyukikai), Omni Mixer (yamato scientific co. ltd.), Homogenizer (STM), and the like.

Since particles are produced from a reaction solution, unwanted substances such as a by-product, an excessive amount of dispersant, and the like may be removed by a well known method, such as decantation, centrifugation, ultrafiltration (UF). As for the cleaning solution, alcohol, water, or a mixed solution of alcohol and water is used, and cleaning is performed in such a manner as to avoid aggregation and dryness.

With respect to the method of forming metal-chalcogen particles, a metal salt or comoplex and a chalcogen salt or comoplex may be included in a reverse micelle and mixed, thereby causing a reaction between them. Further, a reducing agent may be included in the reverse micelle while the reaction is taking place. More specifically, a method described, for example, in Japanese Unexamined Patent Publication No. 2003-239006, Japanese Unexamined Patent Publication No. 2004-052042, or the like may be cited as a reference. Further, a particle forming method through a molecular cluster described in PCT Japanese Publication No. 2007-537866 may also be used.

Still further, particle forming methods described in the following documents may also be used: PCT Japanese Publication No. 2002-501003; U.S. Patent Application Publication No. 20050183767; International Patent Publication No. WO2006/009124; “Synthesis of Chalcopyrite Nanoparticles via Thermal Decomposition of Metal-Thiolate”, T. Kino et al., Materials Transaction, Vol. 49, No. 3, pp. 435-438, 2008, “Cu(In,Ga)(S,Se)₂ solar cells and modules by electrodeposition”, S. Taunier et al., Thin Solid Films, Vols. 480-481, pp. 526-531, 2005; “Synthesis of CuInGaSe₂ nanoparticles by solvothermal route”, Y. G. Chun et al., Thin Solid Films, Vols. 480-481, pp. 46-49, 2005; “Nucleation and growth of Cu(In,Ga)Se₂ nano particles in low temperature colloidal process”, S. Ahn et al., Thin Solid Films, Vol. 515, Issues 7-8, pp. 4036-4040, 2007; “Cu—In—Ga—Se nanoparticle colloids as spray deposition precursors for Cu(In,Ga)Seₑ solar cell materials”, D. L. Schulz et al., Journal of Electronic Materials, Vol. 27, No. 5, pp. 433-437, 2007; and the like.

### <Coating Process>

There is not any specific restriction on the method of coating, on a substrate, a plurality of particles or a coating material that includes a plurality of particles and a dispersion medium. Preferably, the substrate is sufficiently dried prior to the coating process.

As for the coating method, web coating, spray coating, spin coating, doctor blade coating, screen printing, ink-jetting, or the like may be used. The web coating, screen printing, and ink-jetting are particularly preferable because they allow roll-to-roll manufacturing on a flexible substrate.

The dispersion medium may be used as required. Liquid dispersion media, such as water, organic solvent, and the like are preferably used. As for the organic solvent, polar solvents are preferable, and alcohol based solvents are more preferable. The alcohol based solvents include methanol, ethanol, propanol, butanol, methoxyethanol, ethoxyethanol, ethoxypropanol, tetrafluoropropanol, and the like, and ethoxyethanol, ethoxypropanol, or tetrafluoropropanol is preferably used. As for the solution properties of the coating material, including the viscosity, surface tension, and the like, are adjusted in preferable ranges using a dispersion medium described above according to the coating method employed.

As for the dispersion medium, a solid dispersion medium may also be used. Such solid dispersion media include, for example, the absorption group containing low molecular dispersant described above and the like.

When spherical particles are coated on a substrate, the particles are spontaneously disposed on the substrate in close packed manner to form a particle layer. When plate-like particles are coated on a substrate, the particles are spontaneously disposed on the substrate such that the main surfaces thereof are arranged parallel to the surface of the substrate, thereby forming a particle layer.

In the present invention, the particles are stacked in the thickness direction. Here, the particle layers may be formed one by one or simultaneously. Where the composition in the thickness direction is changed, first a single particle layer may be formed using particles having the same composition and then the layer forming may be repeated by changing the composition or a plurality of particle layers having different compositions in the thickness direction may be formed at a time by simultaneously supplying a plurality types of particles having different compositions.

### <Dispersion Medium Removal Step>

Where a dispersion medium is used, a dispersion medium removal step may be performed, as required, after the coating step described above. Preferably, the dispersion medium removal step is a step performed at a temperature not higher than 250° C.

Liquid dispersion media such as water, organic solvent, and the like may be removed by normal pressure heat drying, reduced pressure drying, reduced pressure heat drying, and the like. Liquid dispersion media such as water, organic solvent, and the like can be sufficiently removed at a temperature not higher than 250° C. Solid dispersion media can be removed by solvent melting, normal pressure heating, or the like. Most organic substances are decomposed at a temperature not higher than 250° C., so that solid dispersion media can be sufficiently removed at a temperature not higher than 250° C.

In this way, the photoelectric conversion semiconductor layer of the present invention may be formed. The photoelectric conversion semiconductor layer of the present invention may be formed by a non-vacuum process, resulting in a reduced cost than that of a layer produced by a vacuum film forming. Further, the present invention does not implement sintering at a temperature higher than 250° C. so that a high temperature processing system is not required, resulting in a low manufacturing cost.

The present invention does not implement sintering at a temperature higher than 250° C. Therefore, if a plurality of types of particles having different compositions is used, the compositions are not unified and each composition is maintained as it is even after the layer is formed. Thus, by the use of a plurality of types of particles, as the plurality of particles, having different band-gaps, the photoelectric conversion semiconductor layer of the present invention may provide a potential distribution in the thickness direction. Consequently, the present invention may provide graded band structures, such as the single grating structure, double grating structure, and the like and a higher photoelectric conversion efficiency than that of a layer formed by a conventional non-vacuum film forming.

As described above, according to the present invention, a photoelectric conversion semiconductor layer capable of providing a potential gradient in the thickness direction, can be manufactured at a lower cost than a layer formed by vacuum film forming, and capable of providing a higher photoelectric conversion efficiency than a layer formed by conventional non-vacuum film forming and a manufacturing method thereof are provided.

As the plurality of particles constituting the photoelectric conversion semiconductor layer of the present invention, plate-like particles are used more preferably. This may provide a larger contact area between the photoelectric conversion layer and an electrode, resulting in a smaller contact resistance, as well as larger contact area between the particles and larger light receiving area for each particle. Consequently, a high photoelectric conversion efficiency may be realized.

Preferably, the dispersion degree is in the range from 20 to 60% for spherical particles having an aspect ratio of 3.0 or less. Use of particles having such dispersion degree allows a particle filling rate of 50% or more to be obtained, whereby light absorption rate per unit thickness of the photoelectric conversion semiconductor layer may be increased and defects causing loss in carrier movement are prevented. Therefore, a high efficient photoelectric conversion semiconductor layer may be realized.

### [Photoelectric Conversion Device]

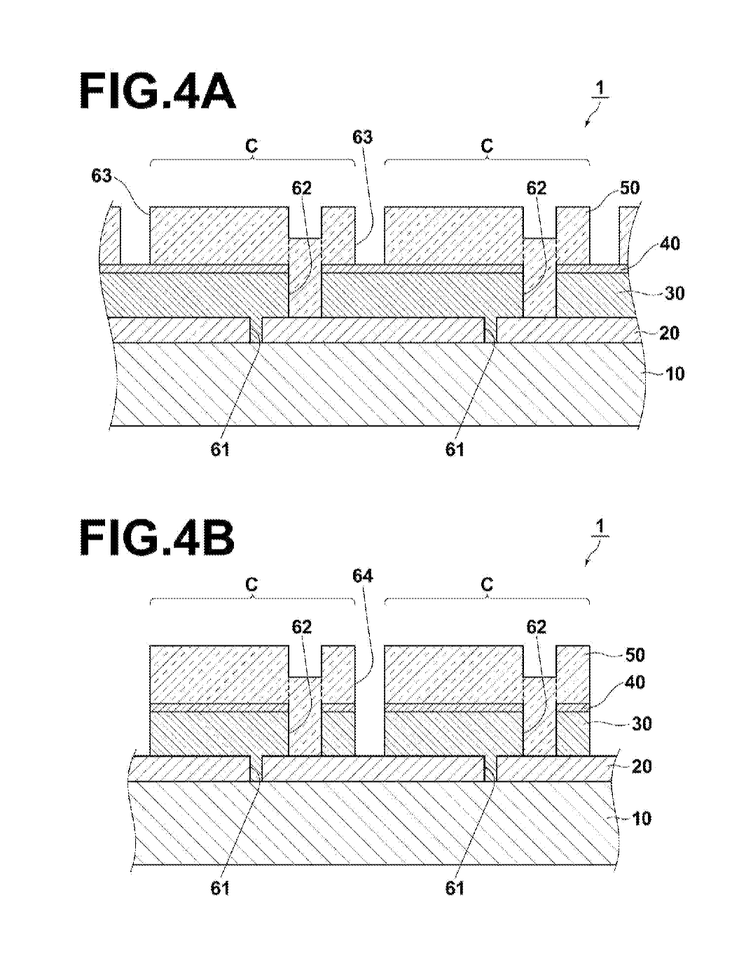

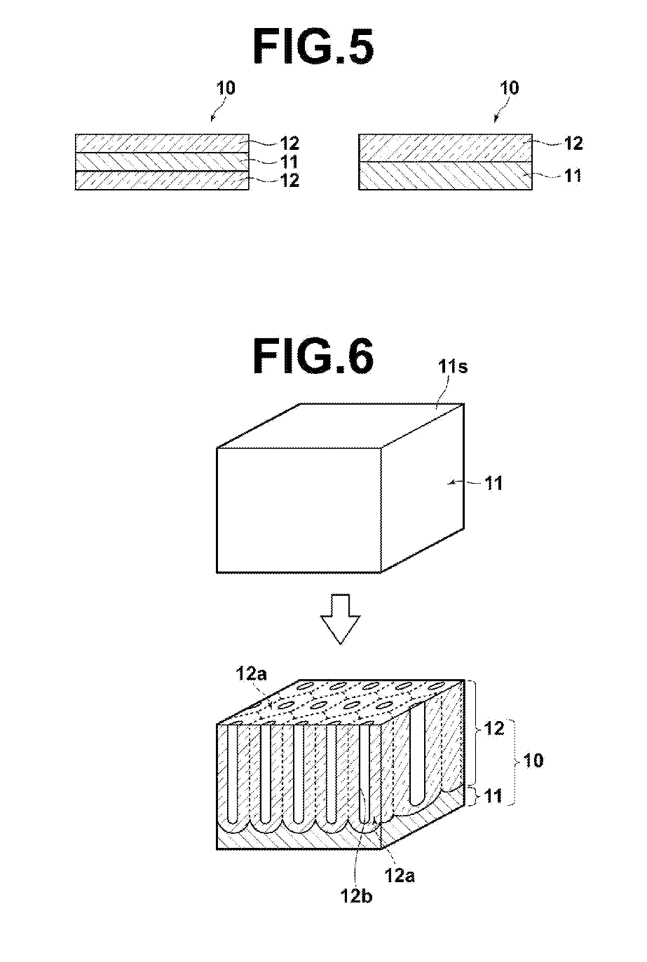

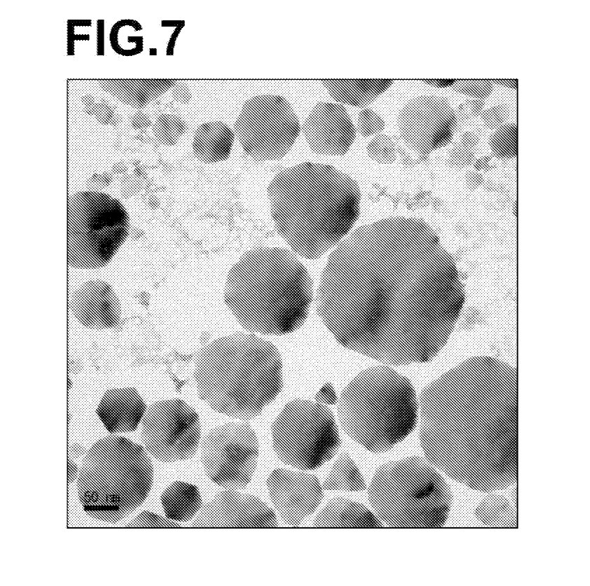

A structure of a photoelectric conversion device according to an embodiment of the present invention will be described with reference to the accompanying drawings. FIG. 4A is a schematic sectional view of the photoelectric conversion device in a lateral direction, and FIG. 4B is a schematic sectional view of the photoelectric conversion device in a longitudinal direction. FIG. 5 is a schematic sectional view of an anodized substrate, illustrating the structure thereof, and FIG. 6 is a perspective view of an anodized substrate, illustrating a manufacturing method thereof. In the drawings, each component is not drawn to scale in order to facilitate visual recognition.

Photoelectric conversion device 1 is a device having substrate 10 on which lower electrode (rear electrode) 20, photoelectric conversion semiconductor layer 30, buffer layer 40, and upper electrode (transparent electrode) 50 are stacked in this order. Photoelectric conversion semiconductor layer 30 is photoelectric conversion semiconductor layer 30X formed of a particle layer in which a plurality of spherical particles 31 is disposed in the plane direction and thickness direction (FIG. 1A) or photoelectric conversion semiconductor layer 30Y formed of a particle layer in which a plurality of plate-like particles 32 is disposed in the plane direction and thickness direction (FIG. 1B).

Photoelectric conversion device 1 has first separation grooves 61 that run through only lower electrode 20, second separation grooves 62 that run through photoelectric conversion layer 30 and buffer layer 40, and third separation grooves 63 that run through only upper electrode layer 50 in a lateral sectional view and fourth separation grooves 64 that run through photoelectric conversion layer 30, buffer layer 40, and upper electrode layer 50 in a longitudinal sectional view.

The above configuration may provide a structure in which the device is divided into many cells C by first to fourth separation grooves 61 to 64. Further, upper electrode 50 is filled in second separation grooves 62, whereby a structure in which upper electrode 50 of a certain cell C is serially connected to lower electrode 20 of adjacent cell C may be obtained.

(Substrate)

In the present embodiment, substrate 10 is an anodized substrate having an Al base consisting primarily of Al having an Al₂O₃ based anodized film on at least either one of the sides. Anodized substrate 10 may have anodized film 12 on each side of Al base 11 as illustrated on the left of FIG. 5 or on either one of the sides thereof as illustrated on the right of FIG. 5.

Preferably, substrate 10 is a substrate of Al base 11 with anodized film 12 on each side as illustrated on the left of FIG. 5 in order to prevent warpage of the substrate due to the difference in thermal expansion coefficient between Al and Al₂O₃, and detachment of the film due to the warpage during the device manufacturing process. The anodizing method for both sides may include, for example, a method in which anodization is performed on a side-by-side basis by applying an insulation material and a method in which both sides are anodized at the same time.

When anodized film 12 is formed on each side of anodized substrate 10, it is preferable that two anodized films are formed to have substantially the same film thickness or anodized film 12 on which a photoelectric conversion layer and some other layers are not provided is formed to have a slightly thicker film thickness than that of the anodized film 12 on the other side in consideration of heat stress balance between each side.

Al base 11 may be Japanese Industrial Standards (JIS) 1000 pure Al or an alloy of Al with another metal element, such as Al—Mn alloy, Al—Mg alloy, Al—Mn—Mg alloy, Al—Zr alloy, Al—Si alloy, Al—Mg—Si, or the like (Aluminum Handbook, Fourth Edition, published by Japan Light Metal Association, 1990). Al base 11 may include traces of various metal elements, such as Fe, Si, Mn, Cu, Mg, Cr, Zn, Bi, Ni, Ti, and the like.

Anodization may be performed by immersing Al base 11, which is cleaned, smoothed by polishing, and the like as required, as an anode together with a cathode in an electrolyte, and applying a voltage between the anode and cathode. As for the cathode, carbon, aluminum, or the like is used. There is not any specific restriction on the electrolyte, and an acid electrolyte containing one type or more types of acids, such as sulfuric acid, phosphoric acid, chromic acid, oxalic acid, sulfamic acid, benzenesulfonic acid, amido-sulfonic acid, and the like, is preferably used.

There is not any specific restriction on the anodizing conditions, which are dependent on the electrolyte used. As for the anodizing conditions, for example, the following are appropriate: electrolyte concentration of 1 to 80% by mass; solution temperature of 5 to 70° C.; current density in the range from 0.005 to 0.60 A/cm²; voltage of 1 to 200 V; and electrolyzing time of 3 to 500 minutes.

As for the electrolyte, a sulfuric acid, a phosphoric acid, an oxalic acid, or a mixture thereof may preferably be used. When such an electrolyte is used, the following conditions are preferable: electrolyte concentration of 4 to 30% by mass, solution temperature of 10 to 30° C., current density in the range from 0.05 to 0.30 A/cm², and voltage of 30 to 150 V.

As shown in FIG. 6, when Al base 11 is anodized, an oxidization reaction proceeds from surface 11s in a direction substantially perpendicular to surface 11s, and Al₂O₃ based anodized film 12 is formed. Anodized film 12 generated by the anodization has a structure in which multiple fine columnar bodies, each having a substantially regular hexagonal shape in plan view, are tightly arranged. Each fine columnar body 12a has a fine pore 12b, substantially in the center, extending substantially linearly in a depth direction from surface 11s, and the bottom surface of each fine columnar body 12a has a rounded shape. Normally, a barrier layer without any fine pore 12b is formed (generally, with a thickness of 0.01 to 0.4 μm) at a bottom area of fine columnar bodies 12a. Anodized film 12 without any fine pore 12b may also be formed by appropriately arranging the anodizing conditions.

There is not any specific restriction on the diameter of fine pore 12b of anodized film 12. Preferably the diameter of fine pore 12b is 200 nm or less, and more preferably 100 nm or less from the viewpoints of surface smoothness and insulation properties. It is possible to reduce the diameter of fine pore 12b to about 10 nm.

There is not any specific restriction of the pore density of fine pores 12b of anodized film 12. Preferably, the pore density of fine pores 12b is 100 to 10000/μm², and more preferably 100 to 5000 μm², and particularly preferably 100 to 1000/μm² from the viewpoint of insulation properties.

There is not any specific restriction on the surface roughness Ra. From the viewpoint of uniformly forming the upper layer of photoelectric conversion layer 30, high surface smoothness is desirable. Preferably, the surface roughness Ra is 0.3 μm or less, and more preferably 0.1 μm or less.

There is not any specific restriction on the thicknesses of Al base 11 and anodized film 12. Preferably, the thickness of Al base 11 prior to anodization is, for example, 0.05 to 0.6 mm, and more preferably 0.1 to 0.3 mm in consideration of the mechanical strength of substrate 10, and reduction in the thickness and weight. When the insulation properties, mechanical strength, and reduction in the thickness and weight are taken into account, a preferable range of the thickness of anodized film 12 is 0.1 to 100 μm.

Fine pores 12b of anodized film 12 may be sealed by any known sealing method as required. The sealed pores may increase the withstand voltage and insulating property. Further, if the pores are sealed using a material containing an alkali metal, when photoelectric conversion layer 30 of CIGS or the like is annealed, the alkali metal, preferably Na, diffuses in photoelectric conversion layer 30, whereby the crystallization of photoelectric conversion layer 30, and hence photoelectric conversion efficiency, may sometimes be improved.

(Electrodes, Buffer Layer)

Each of lower electrode 20 and upper electrode 50 is made of a conductive material. Upper electrode 50 on the light input side needs to be transparent. There is not any specific restriction on the major component of lower electrode 20 and Mo, Cr, W, or a combination thereof is preferably used, in which Mo is particularly preferable. There is not any specific restriction on the thickness of lower electrode 20 and a value in the range from 0.3 to 1.0 μm is preferably used. There is not any specific restriction on the major component of upper electrode 50 and ZnO, ITO (indium tin oxide), SnO₂, or a combination thereof is preferably used. There is not any specific restriction on the thickness of upper electrode 50 and a value in the range from 0.6 to 1.0 μm is preferably used. Lower electrode 20 and/or upper electrode 50 may have a single layer structure or a laminated structure, such as a two-layer structure. There is not any specific restriction on the method of forming lower electrode 20 and upper electrode 50, and vapor deposition methods, such as electron beam evaporation and sputtering may be used.

There is not any specific restriction on the major component of buffer layer 40 and CdS, ZnS, ZnO, ZnMgO, ZnS (O,OH), or a combination thereof is preferably used. There is not any specific restriction on the thickness of buffer layer 40 and a value in the range from 0.03 to 0.1 μm is preferably used. A preferable combination of the compositions is, for example, Mo lower electrode/CdS buffer layer/CIGS photoelectric conversion layer/ZnO upper electrode.

There is not any specific restriction on the conductivity type of photoelectric conversion layer 30, buffer layer 40, and upper electrode 50. Generally, photoelectric conversion layer 30 is a p-layer, buffer layer 40 is an n-layer (n-Cds, or the like), and upper electrode 50 is an n-layer (n-ZnO layer, or the like) or has a laminated structure of i-layer and n-layer (i-ZnO layer and n-ZnO, or the like). It is believed that such conductivity types form a p-n junction or a p-i-n junction between photoelectric conversion layer 30 and upper electrode 50. Further, it is thought that provision of CdS buffer layer 40 on photoelectric conversion layer 30 results in an n-layer to be formed in a surface layer of photoelectric conversion layer 30 by Cd diffusion, whereby a p-n junction is formed inside of photoelectric conversion layer 30. It is also conceivable that an i-layer may be provided below the n-layer inside of photoelectric conversion layer 30 to form a p-i-n junction inside of photoelectric conversion layer 30.

(Other Structures)

It is reported that, in a photoelectric conversion device using a soda lime glass substrate, an alkali metal element (Na element) in the substrate is diffused into the CIGS film, thereby improving energy conversion efficiency. In the present embodiment, it is also preferable to diffuse an alkali metal into the photoelectric conversion layer of CIGS and the like.

As for the alkali metal diffusion method, a method in which a layer including an alkali metal element is formed on a Mo lower electrode by deposition or sputtering as described, for example, in Japanese Unexamined Patent Publication No. 8 (1996)-222750, a method in which an alkali layer of Na₂S or the like is formed on a Mo lower electrode by soaking process as described, for example, in International Patent Publication No. WO03/069684, a method in which a precursor of In, Cu, and Ga metal elements is formed on a Mo lower electrode and then, for example, an aqueous solution including sodium molybdate is deposited on the precursor, or the like may be cited. A sodium silicate layer may be formed on an insulating substrate for supplying alkali metal elements. A polyacid layer, such as sodium polymolybdate, sodium polytungstate, or the like, may be formed on the upper side or lower side of the Mo electrode for supplying alkali metal elements. Lower electrode 20 may be structured such that a layer of one or more types of alkali metal compounds, such as Na₂S, Na₂Se, NaCl, NaF, and sodium molybdate salt, is formed inside thereof.

Photoelectric conversion device 1 may have any other layer as required in addition to those described above. For example, a contact layer (buffer layer) for enhancing the adhesion of layers may be provided, as required, between substrate 10 and lower electrode 20, and/or between lower electrode 20 and photoelectric conversion layer 30. Further, an alkali barrier layer for preventing diffusion of alkali ions may be provided, as required, between substrate 10 and lower electrode 20. For details of the alkali barrier layer, refer to Japanese Unexamined Patent Publication No. 8 (1996)-222750.

Photoelectric conversion device 1 of the present embodiment is structured in the manner as described above. The photoelectric conversion device 1 of the present embodiment includes photoelectric conversion semiconductor layer 30 of the present invention, so that it can be manufactured at a low cost and has a higher photoelectric conversion efficiency than that produced by a conventional non-vacuum film forming.

Photoelectric conversion device 1 may preferably be used as a solar cell. It can be turned into a solar cell by attaching, as required, a cover glass, a protection film, and the like.

(Design Changes)

The present invention is not limited to the embodiments described above, and design changes may be made as appropriate without departing from the sprit of the invention.

In the aforementioned embodiment, the description has been made of a case in which anodized substrate 10 constituted by an Al base having an Al₂O₃ based anodized film on at least either one of the sides is used.

But, any known substrates including, for example, glass substrates, metal substrates, such as stainless, with an insulation film formed thereon, substrates of resins, such as polyimide, may also be used. The photoelectric conversion device of the present invention can be manufactured by non-vacuum processing and a high temperature heat treatment is not performed, so that the device can be manufactured quickly through a continuous conveyance system (roll-to-roll process). Accordingly, the use of a flexible substrate, such as an anodized substrate, a metal substrate with an insulation film formed thereon, or a resin substrate is preferable. The present invention does not require a high temperature process so that an inexpensive and flexible resin substrate may also be used.

In order to prevent warpage of the substrate due to thermal stress, it is preferable that the difference in thermal expansion coefficient between the substrate and each layer formed thereon is small. Among the different types of substrates described above, the anodized substrate is particularly preferable from the viewpoint of difference in thermal expansion coefficient with the photoelectric conversion layer or lower electrode (rear electrode), cost, and characteristics required of solar cells or from the viewpoint of easy formation of an insulation film even on a large substrate without any pinhole.

As for the anodized substrate, other than anodized substrate 10 described in the embodiment above, an anodized substrate constituted by a composite base of a Fe material primarily consisting of Fe with an Al material primarily consisting of Al attached on at least either one of the sides of the Fe material and an Al₂O₃ based anodized film formed on at least either one of the sides of the composite base or an anodized substrate of a base constituted by an Fe material primarily consisting of Fe with an Al film primarily consisting of Al formed on at least either one of the Fe material and an Al₂O₃ based anodized film formed on at least either one of the base is preferably used. As for the Fe material, stainless or the like is preferably used.

### EXAMPLES

Examples of the present invention and comparable examples will now be described.

(Synthesis of Spherical Particles P1 to P3)

After generating small particles (particle size of 10 to 20 nm) by mixing CuI, InI₃, GaI₃, and Na₂Se in pyridine at 0° C., the temperature was increased to 20° C. and CuI, InI₃, GaI₃, and Na₂Se were gradually added to obtain submicron Cu(In,Ga)Se₂ (CIGS) spherical particles. After the reaction was completed, the obtained particles were isolated by centrifugation. Three types of spherical particles P1 to P3 having different Ga concentrations were prepared by changing the material composition as follows.
Spherical Particle P1: CIGS spherical particle with a Ga content of 4.3 at %
Spherical Particle P2: CIGS spherical particle with a Ga content of 6.5 at %
Spherical Particle P3: CIGS spherical particle with a Ga content of 8.8 at %

TEM observation of the obtained spherical particles showed that the average particle diameter of each type of the particles was 0.2 μm. Coefficients of variation (dispersion degrees) of particle diameters were 29% (P1), 31% (P2), and 35% (P3) respectively.

(Synthesis of Spherical Particles P4 to P6)

After generating small particles (particle size of 10 to 20 nm) by mixing CuI, AgClO₄, InI₃, GaI₃, and Na₂Se in pyridine at 0° C., the temperature was increased to 20° C. and CuI, AgClO₄, InI₃, GaI₃, and Na₂Se were gradually added to obtain submicron (Cu, Ag) particles. Then, the obtained particles were isolated in the same manner as in spherical particles 1 to 3. Three types of spherical particles P4 to P6 having different Ag concentrations were prepared by changing the material composition as follows.
Spherical Particle P4: (Cu,Ag)(In,Ga)Se₂ spherical particle with an Ag content of 6.4 at %
Spherical Particle P5: (Cu,Ag)(In,Ga)Se₂ spherical particle with an Ag content of 9.7 at %
Spherical Particle P6: (Cu,Ag)(In,Ga)Se₂ spherical particle with an Ag content of 12.9 at %

TEM observation of the obtained spherical particles showed that the average particle diameter of each type of the particles was 0.2 μm. Coefficients of variation (dispersion degrees) of particle diameters were 32% (P4), 34% (P5), and 35% (P6) respectively.

(Synthesis of Spherical Particles P7 to P9)

After generating small particles (particle size of 10 to 20 nm) by mixing CuI, InI₃, AlI₃, and Na₂Se in pyridine at 0° C., the temperature was increased to 20° C. and CuI, InI₃, AlI₃, and Na₂Se were gradually added to obtain submicron Cu(In,Al)Se₂ spherical particles. Then, the obtained particles were isolated in the same manner as in spherical particles P1 to P3. Three types of spherical particles P7 to P9 having different Al concentrations were prepared by changing the material composition as follows.
Spherical Particle P7: Cu(In,Al)Se₂ spherical particle with an Al content of 1.7 at
Spherical Particle P8: Cu(In,Al)Se₂ spherical particle with an Al content of 2.6 at
Spherical Particle P9: Cu(In,Al)Se₂ spherical particle with an Al content of 3.6 at %

TEM observation of the obtained spherical particles showed that the average particle diameter and coefficient of variation (dispersion degrees) of particle diameter of each type of the particles were 0.2 μm and 35% respectively.

(Synthesis of Other Spherical Particles)

In the synthesis of spherical particles P1 to P9, the average particle diameters can be changed by changing the amount of components added after the temperature is increased to 20° C. and, for example, particles with average particle diameters in the range from 0.2 to 0.4 μm were obtained. Further, Na₂S was used instead of Na₂Se to obtain spherical particles having similar compositions to those of spherical particles P1 to P9 except that they include S instead of Se.

(Synthesis of Plate-Like Particles P10 to P12)

The inventor of the present invention has succeeded in synthesizing plate-like particles for use in a photoelectric conversion layer by a novel method which is different from the known method described in Non-Patent Document 7. Solutions A and B described below were mixed together with a volume ratio of 1:2 at room temperature (about 25° C.) and the mixed solution was agitated and reacted at 60° C. to synthesize CuIn(S,Se)₂ plate-like particles P10. Then, obtained plate-like particles P10 were isolated in the same manner as in spherical particles P1 to P3.
Solution A: solution prepared by adding hydrazine (0.77M) and 2,2′2″-nitrilotriethanol (1.6M) to aqueous solution of copper sulfate (0.1M) and indium sulfate (0.15M), (pH=8.0)
Solution B: aqueous solution of Na₂S and Na₂Se with a total concentration of 0.9M, (pH=12.0)

The pH of each solution was adjusted with sodium hydroxide.

TEM observation of the obtained plate-like particles showed that the surface shapes of the particles were substantially hexagonal. The average thickness of the particles was 0.4 μm, average equivalent circle diameter was 10.2 μm, coefficient of variation of the average equivalent circle diameter was 320, and aspect ratio was 6.8.

Three types of plate-like particles P10 to P12 having different Se concentrations were prepared by changing the material composition as follows.
Plate-like Particle P10: CuIn(S, Se)₂ plate-like particle with a Se content of 39.8 at %
Plate-like Particle P11: CuIn(S, Se)₂ plate-like particle with a Se content of 35.9 at %
Plate-like Particle P12: CuIn(S, Se)₂ plate-like particle with a Se content of 31.7 at %

The inventor of the present invention has found that the surface shapes of the plate-like particles can be changed by changing the pH of solutions A and B. For example, when the pH was adjusted to 12.0 as in the above, the relationship between the pH of solution A and particle shapes was roughly as follows.
pH of solution A≧12: a spherical shape (not fixed)
pH of solution A=9 to 12: a rectangular solid shape
pH of solution A=8 to 9: a hexagonal plate shape
   When pH of solution A was 8 and pH of solution B was 11, plate-like particles having various different surface shapes were obtained. A TEM photograph thereof is shown in FIG. 7.

Coating materials were prepared using spherical particles P1 to P9 and plate-like particles P10 to P12 with Xeonex (manufactured by Zeon Corporation) as the dispersion medium of each type of particles to produce photoelectric conversion layers. The particle concentration of each coating material was adjusted to 30%.

### Example 1-1

A Mo lower electrode (rear electrode) was formed on a soda lime glass by RF sputtering. The thickness of the lower electrode was 1.0 μm. Next, a coating material dispersed with spherical particles P3 was coated on the substrate having the lower electrode formed thereon to provide a single layer of spherical particles P3 (Ga: 8.8 at %), and a coating material dispersed with spherical particles P2 was coated on the layer of spherical particles P3 to provide a single layer of spherical particles P2 (Ga: 6.5 at %). The dispersion medium was removed by dissolving in toluene and heat drying at 180° C. for 60 minutes. This yielded a CIGS photoelectric conversion layer of two particle layers having a single grating structure.

Next, a semiconductor film having a laminated structure was formed as a buffer layer. First, a CdS film was deposited by chemical deposition with a thickness of about 50 nm. The chemical deposition was performed by heating an aqueous solution containing nitric acid Cd, thiourea, and ammonium to about 80° C. and immersing the photoelectric conversion layer in the solution. Then, a ZnO film was formed on the Cd film with a thickness of about 80 nm by MOCVD.

Next, a B-doped ZnO film was deposited, as an upper electrode, with a thickness of about 500 nm by MOCVD, and Al was deposited as external extraction electrodes, whereby a photoelectric conversion device of the present invention was obtained. The photoelectric conversion efficiency of the device was evaluated using pseudo sunlight of Air Mass (AM)=1.5, 100 mW/cm² and the result was 13%.

### Example 1-2

A photoelectric conversion device of the present invention was obtained in the same manner as in Example 1-1 except that the process for preparing the photoelectric conversion layer was changed as follows. A coating material dispersed with spherical particles P3 was coated on the substrate having the lower electrode formed thereon to provide a single layer of spherical particles P3 (Ga: 8.8 at %), then a coating material dispersed with spherical particles P2 was coated on the layer of spherical particles P3 to provide a single layer of spherical particles P2 (Ga: 6.5 at %), a coating material dispersed with spherical particles P1 was coated on the layer of spherical particles P2 to provide a single layer of spherical particles P1 (Ga: 4.3 at %), and a coating material dispersed with spherical particles P2 was coated on the layer of spherical particles P1 to provide a single layer of spherical particles P2 (Ga: 0.3 at %). The dispersion medium was removed by dissolving in toluene and heat drying at 180° C. for 60 minutes. This yielded a photoelectric conversion layer of four particle layers having a double grating structure. The evaluation result of photoelectric conversion efficiency of the device conducted in the same manner as in Example 1-1 was 14%.

### Example 1-3

A photoelectric conversion device of the present invention was obtained in the same manner as in Example 1-1 except that the process for preparing the photoelectric conversion layer was changed as follows. A coating material dispersed with spherical particles P6 was coated on the substrate having the lower electrode formed thereon to provide a single layer of spherical particles P6 (Ag: 6.4 at %), then a coating material dispersed with spherical particles P5 was coated on the layer of spherical particles P6 to provide a single layer of spherical particles P5 (Ag: 9.7 at %), a coating material dispersed with spherical particles P4 was coated on the layer of spherical particles P5 to provide a single layer of spherical particles P4 (Ag: 12.9 at %), a coating material dispersed with spherical particles P5 was coated on the layer of spherical particles P4 to provide a single layer of spherical particles P5 (Ag: 9.7 at %). The dispersion medium was removed by dissolving in toluene and heat drying at 180° C. for 60 minutes. This yielded a photoelectric conversion layer of four particle layers having a double grating structure. The evaluation result of photoelectric conversion efficiency of the device conducted in the same manner as in Example 1-1 was 12%.

### Example 1-4

A photoelectric conversion device of the present invention was obtained in the same manner as in Example 1-1 except that the process for preparing the photoelectric conversion layer was changed as follows. A coating material dispersed with spherical particles P9 was coated on the substrate having the lower electrode formed thereon to provide a single layer of spherical particles P9 (Al: 3.6 at %), then a coating material dispersed with spherical particles P8 was coated on the layer of spherical particles P9 to provide a single layer of spherical particles P8 (Al: 2.6 at %), a coating material dispersed with spherical particles P7 was coated on the layer of spherical particles P8 to provide a single layer of spherical particles P7 (Al: 1.7 at %), and a coating material dispersed with spherical particles P8 was coated on the layer of spherical particles P7 to provide a single layer of spherical particles P8 (Al: 2.6 at %). The dispersion medium was removed by dissolving in toluene and heat drying at 180° C. for 60 minutes. This yielded a photoelectric conversion layer of four particle layers having a double grating structure. The evaluation result of photoelectric conversion efficiency of the device conducted in the same manner as in Example 1-1 was 13%.

### Example 1-5

Anodization was performed on a base of Al alloy 1050 (Al purity of 99.5%, 0.30 mm thick) to form an anodized film on each side thereof, which was then cleaned with water and dried, whereby an anodized substrate was obtained. The thickness of the anodized film was 9.0 μm (including a barrier layer thickness of 0.38 μm) with a pore diameter of about 100 nm. The anodization was performed in a 16° C. electrolyte which contains 0.5M of oxalic acid using a DC voltage of 40V. A photoelectric conversion layer of the present invention was obtained in the same manner as in Example 1-2 except that the anodized substrate was used instead of the soda lime grass substrate. The evaluation result of photoelectric conversion efficiency of the device conducted in the same manner as in Example 1-1 was 14%.

### Example 1-6

A photoelectric conversion device of the present invention was obtained in the same manner as in Example 1-1 except that the process for preparing the photoelectric conversion layer was changed as follows. A coating material dispersed with plate-like particles P12 was coated on the substrate having the lower electrode formed thereon to provide a single layer of plate-like particles P12 (Se: 31.7 at %), then a coating material dispersed with plate-like particles P11 was coated on the layer of plate-like particles P12 to provide a single layer of plate-like particles P11 (Se: 35.9 at %), a coating material dispersed with plate-like particles P10 was coated on the layer of plate-like particles P11 to provide a single layer of plate-like particles P10 (Se: 39.8 at %), and a coating material dispersed with plate-like particles P11 was coated on the layer of plate-like particles P10 to provide a single layer of plate-like particles P11 (Se: 35.9 at %). The dispersion medium was removed by dissolving in toluene and heat drying at 180° C. for 60 minutes. This yielded a photoelectric conversion layer of four particle layers having a double grating structure. The evaluation result of photoelectric conversion efficiency of the device conducted in the same manner as in Example 1-1 was 13%.

### Comparative Example 1-1

A comparative photoelectric conversion device was obtained in the same manner as in Example 1-1 except that the process for preparing the photoelectric conversion layer was changed as follows. CIGS spherical particles (Ga: 6.5 at %) were synthesized in the same manner as in spherical particles P1 to P3 except that the reaction was performed only at 0° C. The average particle diameter was 15 nm and the coefficient of variation (dispersion degree) of particle diameter was 40%. A coating material was prepared using the synthesized particles and Xeonex (manufactured by Zeon Corporation) as the dispersion medium as in spherical particles P1 to P3.

The prepared coating material was coated on a substrate having a lower electrode formed thereon such that the thickness thereof becomes 0.1 μm after dried. Then, a CIGS photoelectric conversion layer was formed by performing ten minute pre-heating at 200° C. 15 times, sintering at 520° C. for 20 minutes, and oxygen annealing at 180° C. for 10 minutes. The evaluation result of photoelectric conversion efficiency of the device conducted in the same manner as in Example 1-1 was 110.

### Comparative Example 1-2

CIGS spherical particles (Ga: 2.1 at %) were synthesized by the method described in U.S. Pat. No. 6,488,770. The average particle diameter was 1.5 μm and the coefficient of variation of particle diameter was 29%. A coating material was prepared using the synthesized particles and Xeonex (manufactured by Zeon Corporation) as the dispersion medium as in spherical particles P1 to P3.

Then a photoelectric conversion device was obtained according to the method described in Non-patent Document 5 using the spherical particles obtained in the manner as described above. The evaluation result of photoelectric conversion efficiency of the device conducted in the same manner as in Example 1-1 was 10%.

Table 1 below summarizes main manufacturing conditions and evaluation results of each example.

TABLE 1

| | | | | Graded | Band | | C/E |
|---|---|---|---|---|---|---|---|
| | Substrate | Particle | Composition | Element | Grating | Heat Treatment | (%) |
| Eg 1-1 | Glass | Spherical | Cu(InGa)Se(CIGS) | Ga | Sigle | — | 13 |
| Eg 1-2 | Glass | Spherical | Cu(InGa)Se(CIGS) | Ga | Double | — | 14 |
| Eg 1-3 | Glass | Spherical | (CuAg)(InGa)Se | Ag | Double | — | 12 |
| Eg 1-4 | Glass | Spherical | Cu(InAl)Se | Al | Double | — | 13 |
| Eg 1-5 | Anodized | Spherical | Cu(InGa)Se(CIGS) | Ga | Double | — | 14 |
| Eg 1-6 | Glass | P-like | CuIn(S,Se) | Se | Double | — | 13 |
| C/E 1-1 | Glass | Spherical | Cu(InGa)Se(CIGS) | — | — | 200° C. | 11 |
| | | | | | | (15 times) | |
| | | | | | | Sintering | |
| | | | | | | at 520° C. | |
| | | | | | | Annealing at | |
| | | | | | | 180° C. | |
| C/E 1-2 | Glass | Spherical | Cu(InGa)Se(CIGS) | — | — | — | 10 |

### Example 2-1

After generating small particles (particle size of 10 to 20 nm) by mixing CuI, InI₃, GaI₃, and Na₂Se in pyridine at 0° C., the temperature was increased to 20° C. and CuI, InI₃, GaI₃, and Na₂Se were gradually added to obtain CIGS spherical particles having an average particle diameter of 0.2 μm. Ga content was adjusted to 6.5 at %. Thereafter, a quaternary ammonium chloride was added to oleylamine, used as the solvent, and heated to 220° C. to grow spherical particles. TEM observation of the obtained spherical particles showed that the average particle diameter was 0.4 μm, the aspect ratio was 3.0 and the coefficient of variation (dispersion degree) was 25%. A coating material was prepared in the same manner as in spherical particles P1 to P3 for producing a photoelectric conversion layer.

The prepared coating material was coated on a substrate having a Mo lower electrode formed thereon by sputtering such that the thickness thereof becomes 0.1 μm after dried. Then, a CIGS photoelectric conversion layer was formed by heat drying the coating at 250° C. for 60 minutes. The particle filling rate of the photoelectric conversion layer was 52%. Thereafter, a CdS buffer layer was formed by CBD method and a B-doped ZnO upper electrode (transparent electrode) was formed by MOCVD method. Finally, Al external extraction electrodes were provided to complete the manufacture of a photoelectric conversion device. The photoelectric conversion efficiency of the device was 13%.

### Example 2-2

After generating small particles (particle size of 10 to 20 nm) by mixing CuI, InI₃, GaI₃, and Na₂Se in pyridine at 0° C., the temperature was increased to 100° C. and CuI, InI₃, GaI₃, and Na₂Se were gradually added to obtain submicron CIGS spherical particles. Ga content was adjusted to 6.5 at %. TEM observation of the obtained spherical particles showed that the average particle diameter was 0.3 μm, aspect ratio was 2.5, and coefficient of variation (dispersion degree) was 53%. A coating material was prepared in the same manner as in spherical particles P1 to P3 for producing a photoelectric conversion layer. A photoelectric conversion device was obtained by a process identical to that of Example 2-1 using the prepared coating material. The particle filling rate of the photoelectric conversion layer was 62% and the photoelectric conversion efficiency of the device was 14%.

### Example 2-3

After obtaining CIGS particles having an average particle diameter of 0.2 μm by a process identical to that of Example 2-1, a quaternary ammonium chloride was added to oleylamine, used as the solvent, and heated to 240° C. to grow spherical particles. TEM observation of the obtained spherical particles showed that the average particle diameter was 0.4 μm, the aspect ratio was 1.7 and the coefficient of variation (dispersion degree) was 32%. A coating material was prepared in the same manner as in spherical particles P1 to P3 for producing a photoelectric conversion layer. A photoelectric conversion device was obtained by a process identical to that of Example 2-1 using the prepared coating material. The particle filling rate of the photoelectric conversion layer was 71% and the photoelectric conversion efficiency of the device was 15%.

### Example 2-4

A photoelectric conversion device was obtained in the same manner as in Example 2-3 except that an anodized substrate identical to that of Example 1-5 was used instead of the glass substrate. The photoelectric conversion efficiency of the device was 14%.

### Example 2-5

Following three types of CIGS spherical particles having different Ga contents were obtained by a process identical to that of spherical particles P1 to P3 (P21 to P23). More specifically, after generating small particles (particle size of 10 to 20 nm) by mixing CuI, InI₃, GaI₃, and Na₂Se in pyridine at 0° C., the temperature was increased to 15° C. and were gradually added to obtain submicron Cu(In,Ga)Se₂ (CIGS) spherical particles. The time for adding CuI, InI₃, GaI₃, and Na₂Se was reduced to ⅔ of that of spherical particles P1 to P3. By changing the adding time and reaction temperature, the following three types of spherical particles which have the same average particle diameter (0.2 μm) as that of spherical particles P1 to P3 with the following aspect ratios and coefficients of variation (dispersion degrees) were obtained.
Spherical Particle P21: Ga content of 4.3 at %, aspect ratio of 1.4, dispersion degree of 45%
Spherical Particle P22: Ga content of 6.5 at %, aspect ratio of 1.6, dispersion degree of 51%
Spherical Particle P23: Ga content of 8.8 at %, aspect ratio of 1.6, dispersion degree of 55%

Coating materials were prepared in the same manner as in spherical particles P1 to P3 for producing a photoelectric conversion layer. A photoelectric conversion device was obtained by a process identical to that of Example 2-1. The photoelectric conversion layer of the device was formed in the following manner.

A coating material dispersed with spherical particles P23 was coated on a substrate having a Mo lower electrode formed thereon to provide a single layer of spherical particle P23 (Ga: 8.8 at %), then a coating material dispersed with spherical particles P22 was coated on the layer of spherical particles P23 to provide a single layer of spherical particles P22 (Ga: 6.5 at %), a coating material dispersed with spherical particles P21 was coated on the layer of spherical particles P22 to provide a single layer of spherical particles P21 (Ga: 4.3 at %), and a coating material dispersed with spherical particles P22 was coated on the layer of spherical particles P21 to provide a single layer of spherical particles P22 (Ga: 6.5 at %). The dispersion medium was removed by dissolving in toluene and heat drying at 180° C. for 60 minutes. This yielded a CIGS photoelectric conversion layer of four particle layers having a double grating structure. The particle filling rate of the photoelectric conversion device was 75% and the photoelectric conversion efficiency of the device was 16%.

### Comparative Example 2-1

After generating small particles (particle size of 10 to 20 nm) by mixing CuI, InI₃, GaI₃, and Na₂Se in pyridine at 0° C., the temperature was increased to 20° C. and CuI, InI₃, GaI₃, and Na₂Se were gradually added to obtain submicron CIGS spherical particles. TEM observation of the obtained particles showed that the average particle diameter was 0.2 μm, aspect ratio was 4.0, and coefficient of variation (dispersion degree) was 18%. A coating material was prepared in the same manner as in spherical particles P1 to P3 for producing a photoelectric conversion layer.

The prepared coating material was coated on a substrate having a Mo lower electrode formed thereon by sputtering such that the thickness thereof becomes 0.1 μm after dried. Then, a CIGS photoelectric conversion layer was formed by performing ten minute pre-heating at 200° C. 15 times, sintering at 520° C. for 20 minutes, and oxygen annealing at 180° C. for 10 minutes. The particle filling rate of the photoelectric conversion layer was 60%. Thereafter, a CdS buffer layer was formed by CBD method and a B-doped ZnO upper electrode (transparent electrode) was formed by MOCVD method. Finally, Al external extraction electrodes were provided to complete the manufacture of a photoelectric conversion device. The photoelectric conversion efficiency of the device was 12%.

### Example 3-1

A photoelectric conversion device was obtained in the same manner as in comparative example 2-1 except that 60 minute drying at 250° C. was performed instead of ten minute pre-heating at 200° C. 15 times, sintering at 520° C. for 20 minutes, and oxygen annealing at 180° C. for 10 minutes in the photoelectric conversion layer forming process. The photoelectric conversion efficiency of the device was 7%.

### Example 3-2

Solutions A and B described below were mixed together with a volume ratio of 1:2 at room temperature (about 25° C.) and the mixed solution was agitated and reacted at 60° C. for 20 minutes to synthesize CuInS particles.
Solution A: solution prepared by adding hydrazine (0.77M) and 2,2′2″-nitrilotriethanol (1.6M) to aqueous solution of copper sulfate (0.1M) and indium sulfate (0.15M), (pH=8.0)
Solution B: aqueous solution of Na₂S (0.9M) (pH=12.0)

The pH of each solution was adjusted with sodium hydroxide.

TEM observation of the obtained particles showed that they are plate-like particles having a substantially hexagonal shape. The average particle thickness was 0.9 μm, average equivalent circle diameter was 4.1 μm, coefficient of variation (dispersion degree) of the average equivalent circle diameter was 48%, and aspect ratio was 4.5. A coating material was prepared in the same manner as in spherical particles P1 to P3 for producing a photoelectric conversion layer. A photoelectric conversion device was obtained by a process identical to that of Example 2-1 using the prepared coating material. The particle filling rate of the photoelectric conversion layer was 48% the photoelectric conversion efficiency of the device was 11%.

### Example 3-3

After generating small particles (particle size of 10 to 20 nm) by mixing CuI, GaI₃, and Na₂Se in pyridine at 0° C., the temperature was increased to 10° C. and CuI, InI₃, GaI₃, and Na₂Se were gradually added to obtain submicron CIGS spherical particles. TEM observation of the obtained spherical particles showed that the average particle diameter was 0.2 μm, aspect ratio was 3.0, and coefficient of variation (dispersion degree) of particle diameter was 65%. A coating material was prepared in the same manner as in spherical particles P1 to P3 for producing a photoelectric conversion layer. A photoelectric conversion device was obtained by a process identical to that of Example 2-1 using the prepared coating material. The particle filling rate of the photoelectric conversion layer was 47% and the photoelectric conversion efficiency of the device was 8%.

Table 2 below summarizes the results of Examples 2-1 to 2-5, Examples 3-1 to 3-3, and Comparative Example 2-1.

TABLE 2

| | | Particle | | | | | | |
|---|---|---|---|---|---|---|---|---|
| | | Aspect | Disp. | | Graded | Fill Rate | | C/E |
| | Substrate | ratio | (%) | Composition | Element | (%) | Heat Treatment | (%) |
| Eg | Glass | 3.0 | 25 | CIGS | — | 52 | 250° C. | 13 |
| 2-1 | | | | | | | | |
| Eg | Glass | 2.5 | 53 | CIGS | — | 62 | 250° C. | 14 |
| 2-2 | | | | | | | | |
| Eg | Glass | 1.7 | 32 | CIGS | — | 71 | 250° C. | 15 |
| 2-3 | | | | | | | | |
| Eg | Anodized | 1.7 | 32 | CIGS | — | 71 | 250° C. | 14 |
| 2-4 | | | | | | | | |
| Eg | Glass | 1.4 to | 45 to | CIGS | Ga | 75 | 250° C. | 16 |
| 2-5 | | 1.6 | 55 | | | | | |
| Eg | Glass | 4.0 | 18 | CIGS | — | 42 | 250° C. | 7 |
| 3-1 | | | | | | | | |
| Eg | Glass | 4.5 | 25 | CuInS | — | 48 | 250° C. | 11 |
| 3-2 | | | | | | | | |
| Eg | Glass | 3.0 | 65 | CIGS | — | 47 | 250° C. | 8 |
| 3-3 | | | | | | | | |
| C/E | Glass | 4.0 | 18 | CIGS | — | 60 | 200° C. | 12 |
| 2-1 | | | | | | | (15 times) | |
| | | | | | | | Sintering at | |
| | | | | | | | 520° C. | |
| | | | | | | | Annealing at | |
| | | | | | | | 180° C. | |

The photoelectric conversion devices of the present invention and manufacturing methods thereof may preferably be applied to solar cells, infrared sensors, and the like.

1-21. (canceled)

22. A photoelectric conversion semiconductor layer that generates a current by absorbing light, comprising a particle layer in which a plurality of particles is disposed in a plane direction and a thickness direction.

23. The photoelectric conversion semiconductor layer of claim 22, wherein the layer includes, as the plurality of particles, a plurality of types of particles having different band-gaps, and the potential of the layer in the thickness direction is distributed.

24. The photoelectric conversion semiconductor layer of claim 23, wherein a graph representing the relationship between the position of the layer in the thickness direction and the potential has a plurality of slopes.

25. The photoelectric conversion semiconductor layer of claim 24, wherein the layer has a double grating structure in which a graph representing the relationship between the position of the layer in the thickness direction and the potential has two slopes.

26. The photoelectric conversion semiconductor layer of claim 22, wherein the plurality of particles has an aspect ratio of 3.0 or less and a coefficient of variation of particle diameter of 20 to 60%.

27. The photoelectric conversion semiconductor layer of claim 22, wherein the plurality of particles is spherical particles and/or plate-like particles.

28. The photoelectric conversion semiconductor layer of claim 22, wherein a volume filling rate representing the ratio of the total volume of the plurality of particles to the volume of the entire photoelectric conversion semiconductor layer is 50% or more.

29. The photoelectric conversion semiconductor layer of claim 22, wherein the layer includes, as a major component, at least one type of compound semiconductor having a chalcopyrite structure.

30. The photoelectric conversion semiconductor layer of claim 29, wherein the at least one type of compound semiconductor is a semiconductor formed of a group Ib element, a group IIIb element, and a group VIb element.

31. The photoelectric conversion semiconductor layer of claim 30, wherein:
the group Ib element is at least one type of element selected from the group consisting of Cu and Ag;
the group IIIb element is at least one type of element selected from the group consisting of Al, Ga, and In; and
the group VIb element is at least one type of element selected from the group consisting of S, Se, and Te.

32. The photoelectric conversion semiconductor layer of claim 30, wherein the layer includes, as the plurality of particles, a plurality of types of particles having different concentrations of at least one of the group Ib element, group IIIb element, and group VIb element, and the potential of the layer in the thickness direction is distributed.

33. A method of manufacturing the photoelectric conversion semiconductor layer of claim 22, comprising the step of coating the plurality of particles or a coating material that includes the plurality of particles and a dispersion medium on a substrate.

34. A method of manufacturing the photoelectric conversion semiconductor layer of claim 22, comprising the steps of:
coating a coating material that includes the plurality of particles and a dispersion medium on a substrate; and
removing the dispersion medium.

35. The method of claim 34, wherein the step of removing the dispersion medium is a step performed at a temperature not higher than 250° C.

36. A photoelectric conversion device, comprising the photoelectric conversion semiconductor layer of claim 22 and electrodes for extracting a current generated in the photoelectric conversion semiconductor layer.

37. The photoelectric conversion device of claim 36, wherein the device is a device that uses a flexible substrate in which the photoelectric conversion semiconductor layer and the electrodes are provided on the flexible substrate.

38. The photoelectric conversion device of claim 37, wherein the flexible substrate is an anodized substrate that comprises an Al base consisting primarily of Al and having an Al₂O₃ based anodized film on at least either one of the sides.

39. The photoelectric conversion device of claim 37, wherein the flexible substrate is an anodized substrate that comprises a composite base having an Al₂O₃ based anodized film on at least either one of the sides, the composite base being made of a Fe material primarily consisting of Fe with an Al material primarily consisting of Al combined to at least either one of the sides of the Fe material.

39. The photoelectric conversion device of claim 37, wherein the flexible substrate is an anodized substrate that comprises a composite base having an Al₂O₃ based anodized film on at least either one of the sides, the composite base being made of a Fe material primarily consisting of Fe with an Al film primarily consisting of Al formed on at least either one of the sides of the Fe material.

40. A solar cell, comprising the photoelectric conversion device of claim 36.
